(19) United States
(12) Patent Application Publication
(10) Pub. No.: US 2024/0304669 A1
(43) Pub. Date: Sep. 12, 2024

(54) 3DSFET DEVICE INCLUDING RESTRUCTURED LOWER SOURCE/DRAIN REGION HAVING INCREASED CONTACT AREA

(71) Applicant: SAMSUNG ELECTRONICS CO., Ltd., Suwon-si (KR)

(72) Inventors: Keumseok Park, Slingerlands, NY (US); Myung Yang, Niskayuna, NY (US); Kang-ill Seo, Springfield, VA (US)

(73) Assignee: SAMSUNG ELECTRONICS CO., Ltd., Suwon-si (KR)

(21) Appl. No.: 18/233,693

(22) Filed: Aug. 14, 2023

Related U.S. Application Data
(60) Provisional application No. 63/450,567, filed on Mar. 7, 2023.

(51) Int. Cl. H01L 29/08; H01L 21/8234; H01L 27/06; H01L 27/088; H01L 29/06; H01L 29/36; H01L 29/423; H01L 29/66; H01L 29/775; H01L 29/786

(52) U.S. Cl. CPC H01L 29/0847; H01L 21/823418; H01L 27/0688; H01L 27/088; H01L 29/0673; H01L 29/36; H01L 29/42392; H01L 29/66439; H01L 29/775; H01L 29/78696

(57) ABSTRACT

Provided is a three-dimensional field-effect transistor (3DSFET) device including: a 1^{st} source/drain region; and a 2^{nd} source/drain region stacked on the 1^{st} source/drain region, wherein the 1^{st} source/drain region has a protrusion at a 2^{nd} upper corner portion among a 1^{st} upper corner portion and the 2^{nd} upper corner portion opposite to each other in a channel-width direction view.

### CROSS-REFERENCE TO RELATED APPLICATION

This application is based on and claims priority from U.S. Provisional Application No. 63/450,567 filed on Mar. 7, 2023 in the U.S. Patent and Trademark Office, the disclosure of which is incorporated herein in its entirety by reference.

### BACKGROUND

### 1. Field

Apparatuses and methods consistent with example embodiments of the disclosure relate to a three-dimensionally-stacked field-effect transistor (3DSFET) device including a restructured lower source/drain region contact having a deformed shape to provide an increased contact area.

### 2. Description of Related Art

A 3DSFET device including a lower field-effect transistor and an upper field-effect transistor stacked thereon has been introduced in response to fast-growing demand for an integrated circuit having a high device density and performance. Each of the lower and upper field-effect transistors may be a fin field-effect transistor (FinFET), a nanosheet transistor or any other type of transistor. The FinFET has one or more horizontally arranged vertical fin structures as a channel structure of which at least three surfaces are surrounded by a gate structure, and the nanosheet transistor is characterized by one or more nanosheet channel layers vertically stacked on a substrate as a channel structure and a gate structure surrounding all four surfaces of each of the nanosheet channel layers. The nanosheet transistor is referred to as gate-all-around (GAA) transistor, or as a multi-bridge channel field-effect transistor (MBCFET).

However, achieving the high device density in a 3DSFET device presents various challenges including difficulties in formation of a contact structure on a source/drain region of the lower field-effect transistor, respectively. This issue arises because a lower source/drain region for the lower field-effect transistor is vertically overlapped by an upper source/drain region for the upper field-effect transistor in the structure of the 3DSFET device.

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

Various example embodiments provide a 3DSFET device in which a lower source/drain region is restructured to have a deformed shape that may provide an increased contact area for a lower contact structure.

According to an embodiment, there is provided a 3DSFET device which may include: a 1^{st} source/drain region; and a 2^{nd} source/drain region stacked on the 1^{st} source/drain region, wherein the 1^{st} source/drain region has a protrusion at a 2^{nd} upper corner portion among a 1^{st} upper corner portion and the 2^{nd} upper corner portion opposite to each other in a channel-width direction view. The protrusion may be formed on around a center of a top surface of the 1^{st} source/drain region, in a channel-length direction view.

According to an embodiment, the protrusion may be formed such that the 2^{nd} upper corner portion is extended a vertical direction, a horizontal direction and a diagonal direction, in the channel-width direction view.

According to an embodiment, there is provided a 3DSFET device which may include: a 1^{st} source/drain region; and a 2^{nd} source/drain region stacked above the 1^{st} source/drain region, wherein the 1^{st} source/drain region has a deformed shape at a 2^{nd} upper corner portion among a 1^{st} upper corner portion and the 2^{nd} upper corner portion opposite to each other, in a channel-width direction view.

According to an embodiment, the 1^{st} source/drain region may have a greater height at the 2^{nd} upper corner portion than at the 1^{st} upper corner portion, and a greater width at a top surface portion than at a bottom surface portion, in the channel-width direction view.

According to an embodiment, there is provided a method of manufacturing a 3DSFET device. The method may include: forming, on a substrate, a 1^{st} source/drain region and a 2^{nd} source/drain region above the 1^{st} source/drain region; removing a 2^{nd} side edge portion among a 1^{st} side edge portion and the 2^{nd} side edge portion of the 1^{st} source/drain region to expose a portion of the substrate, below the 2^{nd} side edge portion, and a side surface of a reduced 1^{st} source/drain region, that is the 1^{st} source/drain region from which the 2^{nd} side edge portion is removed, in the channel-width direction view; and forming an additional source/drain region based on the portion of the substrate and the side surface of the reduced 1^{st} source/drain region such that the 2^{nd} side edge portion is reformed and a protrusion is formed on the reformed 2^{nd} side edge portion, in the channel-width direction view, to obtain a restructured 1^{st} source/drain region.

According to an embodiment, there is provided a method of manufacturing a 3DSFET device. The method may include: forming, on a substrate, a 1^{st} source/drain region and a 2^{nd} source/drain region above the 1^{st} source/drain region; removing a 2^{nd} upper side edge portion among a 1^{st} upper side edge portion and the 2^{nd} upper side edge portion of the 1^{st} source/drain region to expose a portion of side surface and a portion of a top surface of a reduced 1^{st} source/drain region, that is the 1^{st} source/drain region from which the 2^{nd} upper side edge portion is removed, in the channel-width direction view; and forming an additional source/drain region based on the portion of the side surface and the portion of the top surface of the reduced 1^{st} source/drain region such that the 2^{nd} upper side edge portion is reformed and a protrusion is formed on the reformed 2^{nd} upper side edge portion, in the channel-width direction view.

### BRIEF DESCRIPTION OF DRAWINGS

Example embodiments of the disclosure will be more clearly understood from the following detailed description taken in conjunction with the accompanying drawings.

FIG. 1 illustrates a top plan view of a 3DSFET device in which an upper channel structure and an upper source/drain region have a smaller width than a lower channel structure and a lower source/drain region, respectively.

FIGS. 2A-2D illustrate cross-section views of the 3DSFET device of FIG. 1A taken along lines I-I′, II-II′, III-III′ and IV-IV′, respectively, as shown in FIG. 1A.

FIGS. 3A-3D illustrate a 3DSFET device including a restructured lower source/drain region a having deformed shape, according to embodiments.

FIGS. 4A-4D, 5A-5E, 6A-6D, 7A-7D, 8A-8D and 9A-9D illustrate intermediate semiconductor devices obtained after respective steps of manufacturing a 3DSFET device including restructured lower source/drain regions, according to embodiments.

FIG. 10 illustrates a flowchart of a method of manufacturing a 3DSFET device including a restructured lower source/drain region, according to embodiments.

FIG. 11 is a schematic block diagram illustrating an electronic device including a 3DSFET device 20 shown in FIGS. 1 and 3A-3D to 9A-9D, according to an embodiment.

### DETAILED DESCRIPTION OF EMBODIMENTS

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, nanosheet sacrificial layers, sacrificial isolation layers and channel isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “1^{st}” element or a “2^{nd}” element, respectively, as long as their structural relationship is clearly understood in the context of the descriptions. Similarly, the terms a “lower” element and an “upper” element may be respectively referred to as a “1^{st}” element and a “2^{nd}” element with necessary descriptions to distinguish the two elements.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element discussed below could be termed a 2^{nd} element without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” is used to compare a dimension of two or more elements, the term may cover a “substantially same” dimension.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. For example, the disclosure omits descriptions of materials of a substrate (e.g., silicon, germanium, etc.), a source/drain region (e.g., silicon doped with p-type or n-type impurities), and a gate structure (e.g., copper (Cu), aluminum (Al), cobalt (Co), tungsten (W), titanium (Ti), tantalum (Ta) or their combination).

In order to address the difficulties in forming a contact structure on a source/drain region of an lower field-effect transistor of a 3DSFET, a step-structured 3DSFET in which an upper field-effect transistor has a smaller channel width and a smaller source/drain region width than a lower field-effect transistor has been developed as described below.

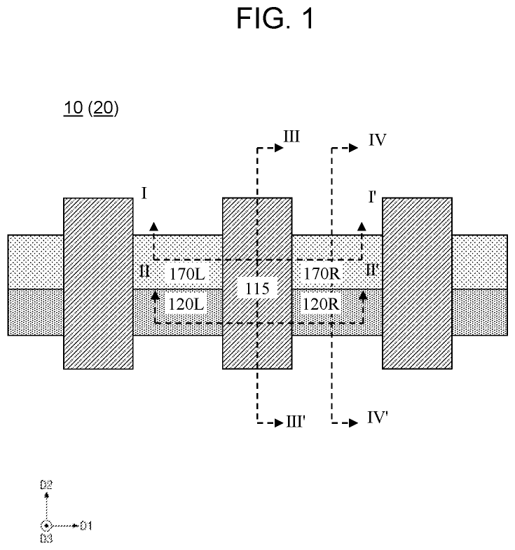

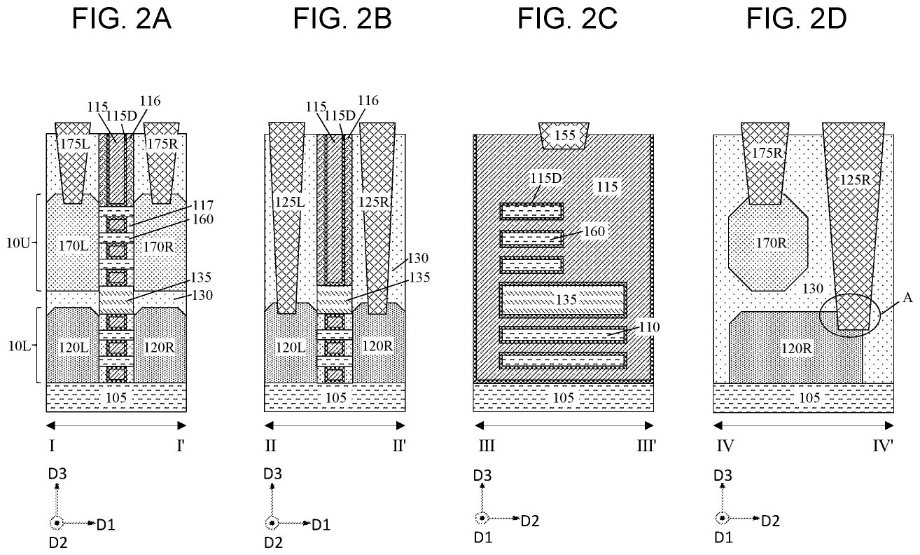

FIG. 1 illustrates a top plan view of a 3DSFET device in which an upper channel structure and an upper source/drain region have a smaller width than a lower channel structure and a lower source/drain region, respectively. FIGS. 2A-2D illustrate cross-section views of the 3DSFET device of FIG. 1A taken along lines I-I′, II-II′, III-III′ and IV-IV′, respectively, as shown in FIG. 1A. It is understood here that FIG. 1 is provided only to show a positional relationship between source/drain regions and gate structures of the 3DSFET device, and thus, other structural elements of the 3DSFET device are not shown therein.

Referring to FIGS. 1 to 2A-2D, a 3DSFET device 10 may include a lower nanosheet transistor 10L formed on a substrate 105 and an upper nanosheet transistor 10U stacked on the lower nanosheet transistor 10L. The two vertically-stacked nanosheet transistors 10L and 10U may be isolated from each other by an interlayer dielectric (ILD) structure 130 and a middle dielectric isolation (MDI) layer 135. The substrate 105 may include a material such as silicon, germanium, or their combination, etc. The ILD structure 130 may include a material such as silicon oxides (SiO, SiO₂, etc.) and the MDI layer 135 may include a material such as silicon nitrides (SiN, SiCN, SiBCN, etc.).

The lower nanosheet transistor 10L may include lower source/drain regions 120L and 120R formed at both ends of a lower channel structure 110 in a D1 direction, which is a channel-length direction. The lower channel structure 110 may include a plurality of lower nanosheet layers and surrounded by a gate dielectric layer 115D and a gate structure 115. Similarly, the upper nanosheet transistor 10U may include upper source/drain regions 170L and 170R formed at both ends of an upper channel structure 160 in the D1 direction. The upper channel structure 160 may include a plurality of upper nanosheet layers and surrounded by the gate structure 115. The nanosheet layers for the channel structures 110 and 160 may be formed of silicon. The gate structure 115 may include a material such as copper (Cu), aluminum (Al), tungsten (W), cobalt (Co), titanium (Ti), tantalum (Ta), or their combination, and the gate dielectric layer 115D may include a high-k material such as hafnium (Hf), not being limited thereto.

The lower source/drain regions 120L and 120R may include silicon or silicon (Si) germanium (SiGe) doped with either p-type impurities (e.g., boron (B), gallium (Ga), indium (In), etc.) or n-type impurities (e.g., phosphorus (P), arsenic (As), antimony (Sb), etc.). The upper source/drain regions 170L and 170R may also be either a p-type or an n-type source/drain region including the above-listed material(s). The lower source/drain regions 120L and 120R may be epitaxially grown from the substrate 105 and the lower channel structure 110, and the upper source/drain regions 170L and 170R may be epitaxially grown from the upper channel structure 160.

To connect the lower and upper source/drain regions 120L, 120R, 170L and 170R to back-end-of-line (BEOL) structures such as a power rail or a metal line for internal routing, lower and upper contact structures 125L, 125R, 175L and 175R may be formed on the lower and upper source/drain regions 120L, 120R, 170L and 170R, respectively. Also, a gate contact structure 155 may be formed on the gate structure 115 to receive a gate input signal from a BEOL structure. These contact structures may be formed of a metal or metal compound of Cu, Al, W, Co, ruthenium (Ru), molybdenum (Mo), etc.

A gate spacer 116 may be formed at side surfaces of the gate structure 115, and an inner spacer 117 may be formed to isolate the gate structure 115 from the source/drain regions 120L, 120R, 170L and 170R. The gate spacer 116 and the inner spacer 117 may include a material such as silicon nitride (SIN, SiCN, SiBCN, etc.).

In the 3DSFET device 10, the upper channel structure 160 may have a smaller channel width than the lower channel structure 110, and the upper source/drain regions 170L and 170R may have a smaller width than the lower source/drain regions 120L and 120R, in a D2 direction (channel-width direction), intersecting the D1 direction (channel-length direction). Thus, as shown in FIG. 2D, for example, the lower contact structure 125R can be vertically extended down from a BEOL structure to a top surface of the lower source/drain region 120R through a non-overlapping region where the upper source/drain region 170R does not overlap the lower source/drain region 120R. Otherwise, in case that the upper source/drain region 170R and the lower source/drain region 120R therebelow have an equal or similar width in the D2 direction, the lower channel structure 125R may not be formed in the non-overlapping region to be connected to the top surface of the lower source/drain region 120R. Instead, for example, the lower contact structure 125R may have to be formed outside the non-overlapping region to be connected to a side surface of the lower source/drain region 120R to avoid a possible short-circuit between the lower contact structure 125R and the upper source/drain region 170R, which only increases the footprint of the 3DSFET device 10.

However, even in the step-structured 3DSFET device 10, a sufficient distance between the lower contact structure 125R and the upper source/drain region 170R is required to avoid a possible short circuit therebetween. Thus, as shown in FIG. 2D, the lower contact structure 125R may be formed to have a marginal contact with an upper-right corner portion A of the lower source/drain region 120R. However, this marginal contact between the lower source/drain region 120R and the lower contact structure 125R reduces a contact area, and thus, a contact resistance therebetween may increase, which leads to degradation of connection performance of the 3DSFET device 10.

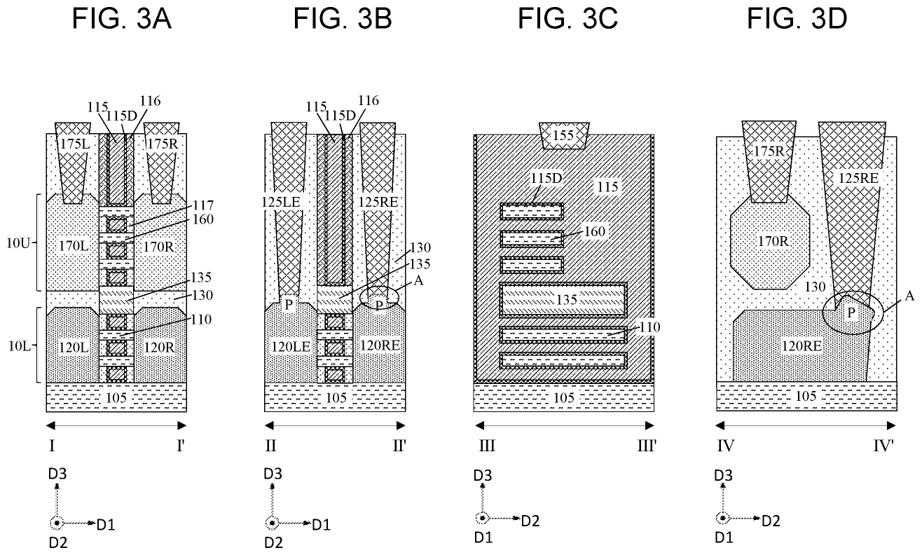

Herebelow, an embodiment of a lower contact structure having an increased contact area and a reduced contact resistance for a 3DSFET device is provided in reference to FIGS. 3A-3D.

FIGS. 3A-3D illustrate a 3DSFET device including a restructured lower source/drain region a having deformed shape, according to embodiments.

Referring to FIGS. 3A-3B, a 3DSFET device 20 includes largely the same structural elements as those of the 3DSFET device 10, and thus, duplicate descriptions of the same structural elements are omitted herein. However, the 3DSFET device 20 differs from the 3DSFET device 10 by lower source/drain regions 120LE, 120RE and lower contact structures 125LE and 125RE which are restructured.

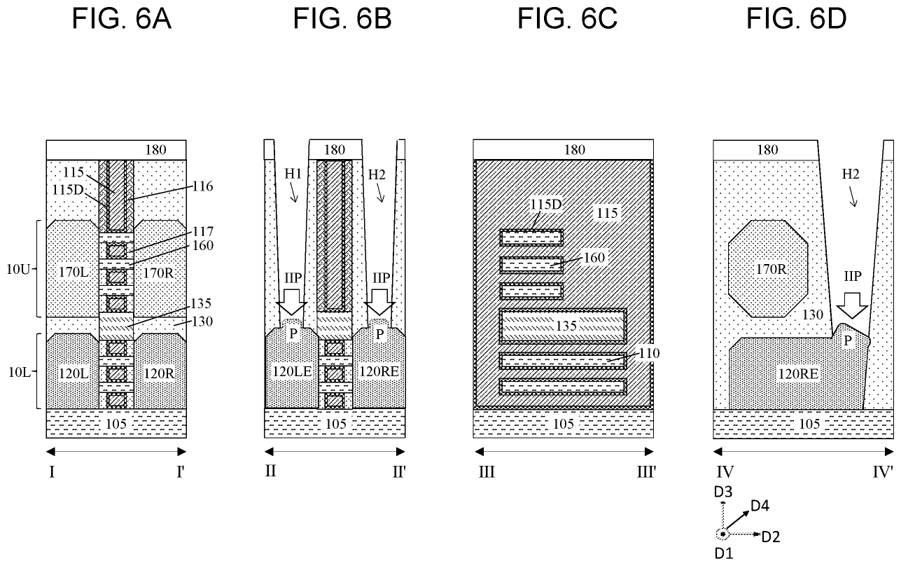

For example, FIGS. 3B and 3D show that the lower source/drain region 120RE has a deformed shape, for example, a protrusion P, at its upper-right corner portion (FIG. 3D) where the lower contact structure 125RE lands for connection thereto. As will be described later in reference to FIGS. 6A-6D, the protrusion may be formed by performing an additional epitaxial growth from the substrate 105 or the lower source/drain region 120RE after the lower source/drain region 120RE is initially grown from the substrate 105 and/or the lower channel structure 110.

As the protrusion P provides an extra contract area for the lower contact structure 125RE, a contact resistance between the two structural elements of the 3DSFET 20 may be reduced. Similarly, the lower source/drain region 120LE may also be formed to have a same or similar protrusion on its upper-right corner in a same-cross section view to facilitate connection with the lower contact structure 125LE. Further, as will be described later in reference to FIGS. 6A-6D, the lower source/drain regions 120LE and 120RE may be additionally doped at least at their right side edge portion including the upper-right corner portions wherein the protrusions P are formed during the formation of the lower source/drain regions 120LE and 120RE, ant thus, the contact resistance may be further reduced and a current output in the lower source/drain regions 120LE and 120RE may increase to enhance the performance of the 3DSFET device 20.

Herebelow, a method of manufacturing the lower source/drain regions 120LE and 120RE of the 3DSFET device 20 is provided.

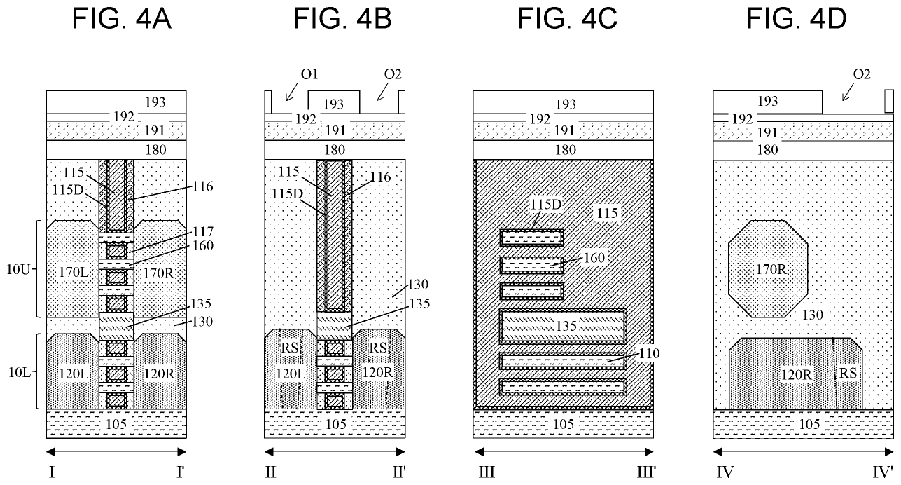

FIGS. 4A-4D to 9A-9D illustrates intermediate semiconductor devices obtained after respective steps of manufacturing a 3DSFET device including restructured lower source/drain regions, according to embodiments. The intermediate semiconductor devices shown in the drawings may include the same structural elements shown in FIGS. 3A-3C, and thus, the same reference numbers and characters may be used in the descriptions herebelow, while duplicate descriptions may be omitted.

Referring to FIGS. 4A-4D, an intermediate semiconductor device provided on a substrate 105 may include a lower channel structure 110 and an upper channel structure 160 having a shorter width than the lower channel structure 110. The intermediate semiconductor device may also include lower source/drain regions 120L, 120R and upper source/drain regions 170L, 170R which have a shorter width than the lower source/drain regions 120L, 120R, respectively. As described earlier in reference to FIGS. 2A-2D, the short-width upper channel structure and source/drain regions may be provided to facilitate formation of lower contact structures on top surfaces of the lower source/drain regions. FIGS. 4B and 4D also show a right side edge portion RS of each of the lower source/drain regions 120L and 120R which will be removed in a next step for restructuring of the lower source/drain regions 120L and 120R in a later step.

The lower source/drain regions 120L and 120R may be doped with p-type or n-type impurities, and the upper source/drain regions 170L and 170R may also be doped with p-type or n-type impurities.

On the intermediate semiconductor device may be provided a masking structure to perform a 1^{st} photolithography and masking operation thereon. For example, the masking structure may include a hard mask structure 180 and a 1^{st} tri-layer structure including an organic planarization layer (OPL) 191, a silicon-containing anti-reflective coating (SiARC) layer 192, and a photoresist pattern 193 having 1^{st} and 2^{nd} openings O1 and O2. These openings O1 and O2 may correspond to horizontal positions where lower contact structures are to be formed to be connected to the lower source/drain regions 120L and 120R, respectively, in a later step.

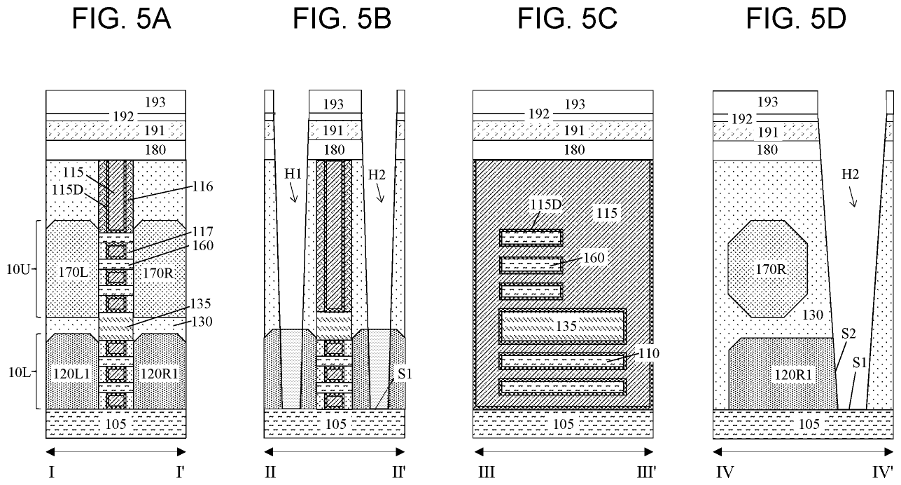

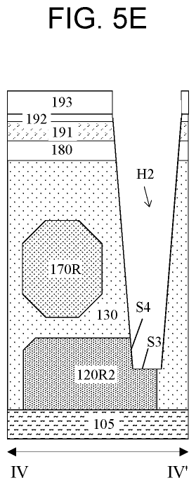

Referring to FIGS. 5A-5D, a masking and etching operation may be performed on the intermediate semiconductor device based on the masking structure including the 1^{st} tri-layer structure and the hard mask structure 180 to form 1^{st} and 2^{nd} holes H1 and H2 penetrating the intermediate semiconductor device. The etching operation may be performed through, for example, dry and/or wet etching.

The masking and etching operation in this step may be performed by patterning the hard mask structure 180 to correspond to the photoresist pattern 193, removing the 1^{st} tri-layer structure, and dry and/or wet-etching the intermediate semiconductor device based on the patterned hard mask structure 180.

By this top-down etching operation, the 2^{nd} hole H2 may penetrate through the ILD layer 130 below the hard mask structure 180 and remove the right side edge portion RS (shown in FIGS. 4B and 4D) of the lower source/drain region 120R to obtain a reduced lower source/drain region 120R1, that is the lower source/drain region 120R from which the right side edge portion RS is removed. As the right side edge portion RS of the lower source/drain region 120R is removed or reduced, a portion S1 of a top surface of the substrate 105 and a side surface S2 of the reduced lower source/drain region 120R1 may be exposed to an outside. When a bottom dielectric isolation (BDI) layer is formed on the substrate 105 and below the lower source/drain region 125R (not shown), the 2^{nd} hole H2 may also penetrate through the BDI layer to expose the portion S1 of the top surface of the substrate 105 in this step. In a later step, an additional epitaxy may be performed based on the exposed portion S1 of the top surface of the substrate 105 and the exposed side surface S2 of the reduced lower source/drain region 120R1 to obtain a restructured lower source/drain region having an increase contact area.

In the same or substantially same manner, the 1^{st} hole H1 may be formed to penetrate through the ILD layer 130 below the hard mask structure 180 and remove the right side edge portion RS of the lower source/drain region 120L to obtain a reduced lower source/drain region 120L1. Thus, duplicate descriptions may be omitted herein.

However, the top-down etching for a later additional epitaxy may be performed to obtain a differently formed lower source/drain region 120R. Referring to FIG. 5E, corresponding to FIG. 5D, the 2^{nd} hole H2 may be formed to remove only an upper-right side edge portion of the lower source/drain region 120R without removing the entire right side edge portion as shown in FIG. 5D, thereby obtaining a reduced lower source/drain region 120R2, that is the lower source/drain region 120R from which the upper-right side edge portion is removed. As the upper-right side edge portion of the lower source/drain region 120R is removed, a portion S3 of a top surface and a portion S4 of a right side surface of the reduced lower source/drain region 120R2 may be exposed to an outside so that, in a later step, an additional epitaxy may be performed based on the exposed surfaces S3 and S4 of the reduced lower source/drain regions 120R2 to obtain a restructured lower source/drain region having a protrusion.

Referring to FIGS. 6A-6D, the 1^{st} tri-layer structure including the OPL 191, the SiARC layer 192 and the photoresist pattern 193 may be removed from above the patterned hard mask structure 180 through, for example, stripping and/or ashing, and the reduced lower source/drain regions 120L1 and 120R1 (or 120L2 and 120R2) obtained in the previous step may be restructured based on the hard mask structure 180 so that restructured lower source/drain regions 120LE and 120RE may have a deformed shape at their upper-right corner portions in view of their upper-left corner portions opposite thereto in the D2 direction.

For example, an additional epitaxy may be performed on the portion S1 of the top surface of the substrate 105 and the right side surface S2 of the reduced lower source/drain region 120R1 shown in FIGS. 5B and 5D to reform the right side edge portion RS of the lower source/drain region 120R removed in the previous step, and may form a protrusion P on the reformed right side edge portion RS. Alternatively, an additional epitaxy may be performed on the portion S3 of the top surface and the portion S4 of the right side surface of the reduced lower source/drain region 120R2 shown in FIG. 5E to reform the upper-right side edge portion of the lower source/drain region 120R removed in the previous step, and may form a protrusion P on the reformed upper-right side edge portion.

According to an embodiment, the restructured lower source/drain region 120RE may have the protrusion P at its upper-right corner portion as shown in FIG. 6D according as the reduced lower source/drain region 120R1 or 120R2 may expose a {100} surface, a {110} surface and a {111} surface. Thus, the reduced lower source/drain region 120R1 or 120R2 may be regrown from at least these surfaces in a D4 (diagonal) direction as well as the D1 and D3 directions so that the restructured lower source/drain region 120RE may have a swollen shape at its upper-right corner portion.

Referring back to FIG. 4B, the opening O2 of the photoresist pattern 193 is formed at a horizontal position corresponding to the center portion of the top surface of the lower source/drain region 120R so that the top-down etching operation shown in FIG. 5B can have a sufficient space margin to obtain the reduced lower source/drain region 120R1 and provide for the additional epitaxy from the reduced lower source/drain region 120R1. Thus, the protrusion P may be formed at around a center portion of a top surface of the restructured lower source/drain region 120RE in the cross-section view in the D1 direction as shown in FIG. 6B.

Due to the protrusion P, the restructured lower source/drain region 120RE may have a greater height at the upper-right corner portion than at an upper-left corner portion, and a greater width at a top surface portion than at a bottom surface portion. Accordingly, the restructured lower source/drain region 120RE may provide an increased contact area for a lower contact structure to be connected thereto.

The restructured lower source/drain region 120LE may have the same or substantially same structural shape as the restructured source/drain region 120RE described above, and thus, duplicate descriptions may be omitted.

Moreover, the restructured lower source/drain regions 120LE and 120RE at the reformed right side edge portions RS and upper-right corner portions including the protrusions P may be additionally doped with the same p-type or n-type impurities which exist in the lower source/drain regions 120L and 120R as described in reference to FIGS. 4A-4D. The doping may be performed through, for example, ion implantation. By additionally doping the restructured lower source/drain regions 120LE and 120RE, the contact resistance may be further reduced and a current output from the restructured lower source/drain regions 120LE and 120RE may increase to improve a device performance.

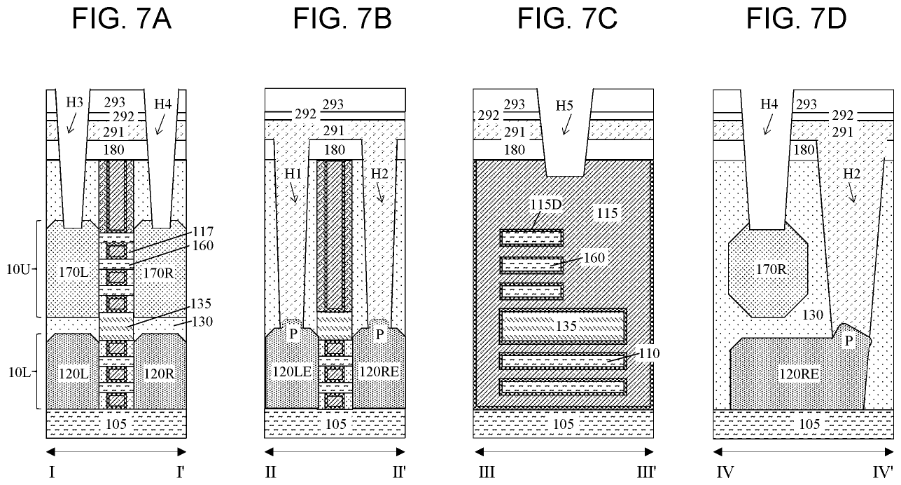

Referring to FIGS. 7A-7D, a 2^{nd} photolithography and masking operation may be performed on the intermediate semiconductor device obtained in the previous step using a 2^{nd} tri-layer structure including an OPL 291, an SiARC layer 292 and photoresist patterns 293 formed on the patterned hard mask structure 280. Based on the 2^{nd} tri-layer structure and the hard mask structure 280, an etching operation such as dry and/or wet etching may be performed to form 3^{rd} to 5^{th} holes H3, H4 and H5 that penetrate through the ILD structure 130 to expose upper source/drain regions 170L, 170R and a gate structure 115 therethrough.

For example, the photoresist patterns 293 may be formed on the SiARC layer 292 such that openings between the photoresist patterns 293 may correspond to horizontal positions where upper contact structures and a gate contact structure are to be formed to be connected to the upper source/drain regions 170L, 170R and the gate structure 115, respectively. Then, a top-down etching operation may be performed based on a masking structure including the 2^{nd} tri-layer structure and the hard mask structure 180 to obtain the holes H3, H4 and H5.

Prior to the top-down etching operation in this step to form the holes H3, H4 and H5, the previously-formed holes H1 and H2 used to obtain the restructured lower source/drain regions 120LE and 120RE may be filled in with the OPL 291 so that these holes may be protected from the top-down etching operation in this step. The OPL 291 may be formed of polymer such as polyimide, not being limited thereto.

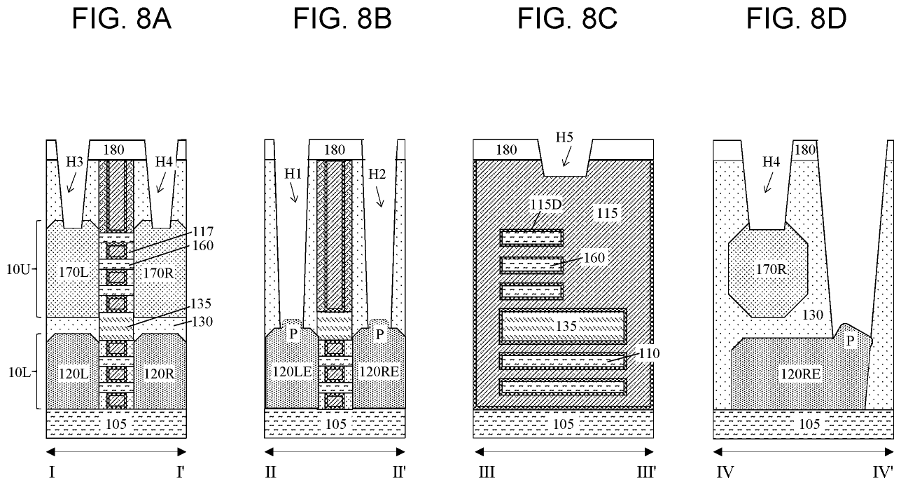

Referring to FIGS. 8A-8D, the 2^{nd} tri-layer structure including the OPL 291 filled in the holes H1 and H2 may be removed from above the hard mask structure 180 through, for example, stripping and/or ashing. Thus, the holes H1 and H2 exposing the upper-right edge portions (FIG. 8D) may be reopened.

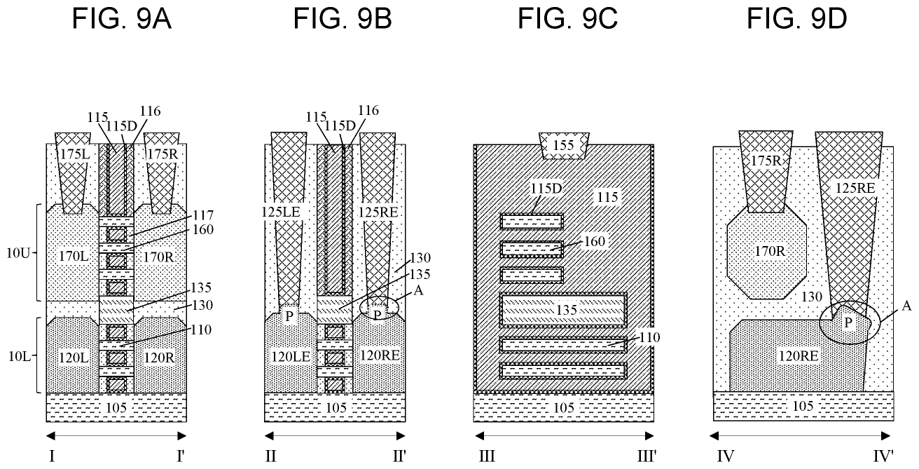

Referring to FIGS. 9A-9D, the holes H1-H5 may be filled in with a metal or metal compound to form lower contact structures 125LE, 125RE, upper contact structures 175L, 175R and a gate contact structure 155, respectively, based on the hard mask structure 180. Thus, a 3DSFET device that is the same as or corresponds to the 3DSFET device 20 shown in FIGS. 1 and 3A-3D may be obtained.

In this step, the lower contact structures 125LE and 125RE may be connected to the protrusions P of the restructured lower source/drain regions 120LE and 120RE through the holes H1 and H2, respectively.

The formation of these contact structures may be performed through, for example, chemical vapor deposition (CVD), plasma enhanced CVD (PECVD), physical vapor deposition (PVD), atomic layer deposition (ALD), or a combination thereof, not being limited thereto. The metal or metal compound used for these depositions may include Cu, Al, W, Co, Ru, Mo, etc., not being limited thereto.

After the formation of the contact structures 125L, 125R, 175L, 175R and 116, the hard mask structure 180 may be removed through, for example, stripping, etching and/or ashing.

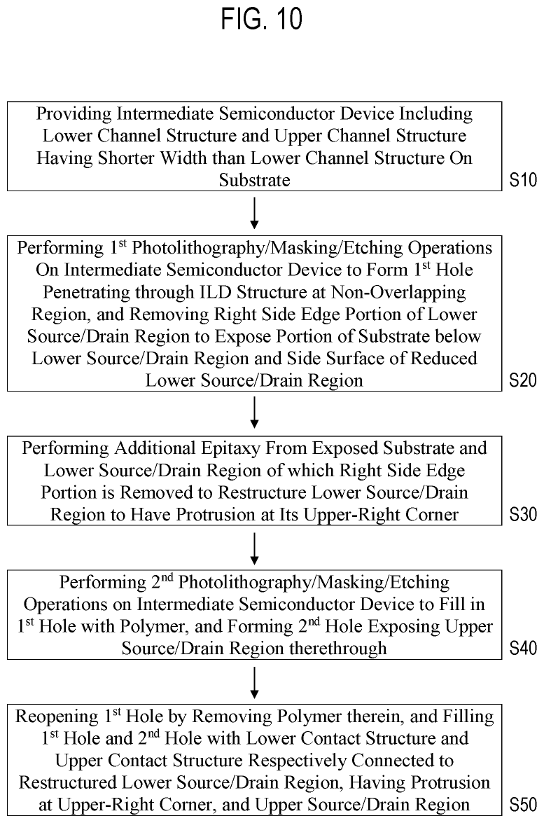

FIG. 10 illustrates a flowchart of a method of manufacturing a 3DSFET device including a restructured lower source/drain region, according to embodiments.

In step S10, an intermediate semiconductor device for a 3DSFET device including a lower channel structure and an upper channel structure having a shorter width than the lower channel structure may be provided on a substrate.

The intermediate semiconductor device may also include a lower source/drain region epitaxially grown from the lower channel structure and doped with impurities and a short-width upper source/drain region epitaxially grown from the upper channel structure and doped with impurities.

Due to this different-width structure of the intermediate semiconductor device, a non-overlapping region where the upper source/drain region does not overlap the lower source/drain region in the intermediate semiconductor device may be formed.

In step S20, 1^{st} photolithography, masking and etching operations may be performed on the intermediate semiconductor device obtained in the previous step to form a 1^{st} hole penetrating through an ILD structure at the non-overlapping region and removing a right side edge portion of the lower source/drain region to expose a portion of the substrate below the lower source/drain region and a side surface of a reduced lower source/drain region, in a D2-direction cross-section view.

Alternatively, the etching operation in this step may form a hole penetrating the ILD structure at the non-overlapping region and only an upper-right side edge portion of the lower source/drain region without removing the entire right edge portion of the lower source/drain region to expose the lower source/drain region.

In step S30, an additional epitaxy may be performed from the exposed substrate and the lower source/drain region of which the right side edge portion is removed to restructure the lower source/drain region to have a protrusion at its upper-right corner.

Additionally, the restructured lower source/drain region including the protrusion may be doped with impurities that are the same as those existing in the lower source/drain region.

In step S40, 2^{nd} photolithography, masking and etching operations may be performed on the intermediate semiconductor device obtained in the previous step to fill in the 1^{st} hole obtained in the previous step with polymer, and form a 2^{nd} hole exposing the upper source/drain region therethrough.

The polymer filled in the hole may protect the 1^{st} hole from the etching operation to form the 2^{nd} hole.

In step S50, the 1^{st} hole may be reopened by removing the polymer filled therein, and the 1^{st} hole and the 2^{nd} hole may be filled in with a lower contact structure and an upper contact structure respectively connected to the restructured lower source/drain region, having the protrusion at the upper-right corner, and the upper source/drain region.

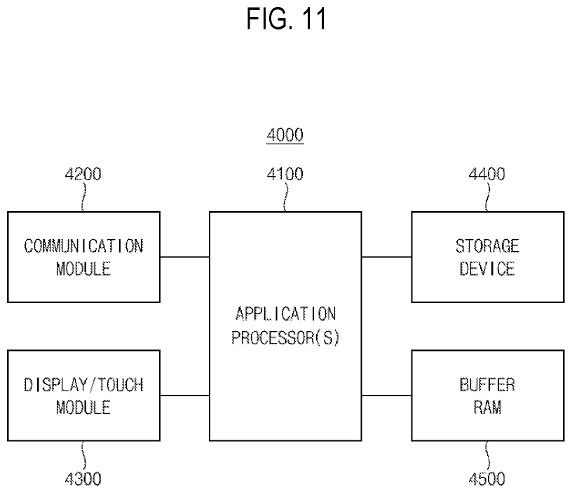

FIG. 11 is a schematic block diagram illustrating an electronic device including a 3DSFET device 20 shown in FIGS. 1 and 3A-3D to 9A-9D, according to an embodiment.

Referring to FIG. 11, an electronic device 4000 may include at least one application processor 4100, a communication module 4200, a display/touch module 4300, a storage device 4400, and a buffer random access memory (RAM) 4500. The electronic device 4000 may be a mobile device such as a smartphone or a tablet computer, not being limited thereto, according to embodiments.

The application processor 4100 may control operations of the electronic device 4000. The communication module 4200 is implemented to perform wireless or wire communications with an external device. The display/touch module 4300 is implemented to display data processed by the application processor 4100 and/or to receive data through a touch panel. The storage device 4400 is implemented to store user data. The storage device 4400 may be an embedded multimedia card (eMMC), a solid state drive (SSD), a universal flash storage (UFS) device, etc. The storage device 4400 may perform caching of the mapping data and the user data as described above.

The buffer RAM 4500 may temporarily store data used for processing operations of the electronic device 4000. For example, the buffer RAM 4500 may be volatile memory such as double data rate (DDR) synchronous dynamic random access memory (SDRAM), low power double data rate (LPDDR) SDRAM, graphics double data rate (GDDR) SDRAM, Rambus dynamic random access memory (RDRAM), etc.

Although not shown in FIG. 6, the electronic device 4000 may further include at least one sensor such as an image sensor.

At least one component in the electronic device 4000 may include the 3DSFET device 20 shown in FIGS. 1 and 3A-3D to 9A-9D.

In the above embodiments, the 3DSFET device 20 is described as being formed of nanosheet field-effect transistors at lower and upper stacks. However, the disclosure is not limited thereto, and at least one of the lower and upper field-effect transistors of the 3DSFET device 20 or 30 may be implemented by a fin field-effect transistor (FinFET) or another type of field-effect transistor.

The foregoing is illustrative of example embodiments and is not to be construed as limiting the disclosure. Although some example embodiments have been described above, those skilled in the art will readily appreciate that many modifications are possible in the above embodiments without materially departing from the disclosure.

1. A three-dimensional field-effect transistor (3DSFET) device comprising:
a 1^{st} source/drain region; and
a 2^{nd} source/drain region stacked on the 1^{st} source/drain region,
wherein the 1^{st} source/drain region has a protrusion at a 2^{nd} upper corner portion among a 1^{st} upper corner portion and the 2^{nd} upper corner portion opposite to each other in a channel-width direction view.

2. The 3DSFET device of claim 1, wherein the protrusion is formed on around a center of a top surface of the 1^{st} source/drain region, in a channel-length direction view.

3. The 3DSFET device of claim 1, wherein the 2^{nd} upper corner portion is in a shape in which the 2^{nd} upper corner portion is protruded in at least a vertical direction, in both the channel-width direction view and a channel-length direction view.

4. The 3DSFET device of claim 3, wherein the 2^{nd} upper corner portion is protruded in a horizontal direction, in the channel-width direction view.

5. The 3DSFET device of claim 4, wherein the 2^{nd} upper corner portion is protruded in a diagonal direction, in the channel-width direction view.

6. The 3DSFET device of claim 1, wherein the 2^{nd} upper corner portion is in a shape in which the 2^{nd} upper corner portion is protruded in at least a horizontal direction, in the channel-width direction view.

7. The 3DSFET device of claim 1, wherein the protrusion comprises p-type impurities or n-type impurities.

8. The 3DSFET device of claim 1, further comprising a contact structure connected to the protrusion.

9. The 3DSFET device of claim 1, wherein a width of the 2^{nd} source/drain region is smaller than a width of the 1^{st} source/drain region, in a channel-width direction view, and
wherein the protrusion is not vertically overlapped by the 2^{nd} source/drain region.

10. A three-dimensional field-effect transistor (3DSFET) device comprising:
a 1^{st} source/drain region; and
a 2^{nd} source/drain region stacked above the 1^{st} source/drain region,
wherein the 1^{st} source/drain region has a deformed shape at a 2^{nd} upper corner portion among a 1^{st} upper corner portion and the 2^{nd} upper corner portion opposite to each other, in a channel-width direction view.

11. The 3DSFET device of claim 10, wherein the 1^{st} source/drain region has a greater height at the 2^{nd} upper corner portion than at the 1^{st} upper corner portion, in the channel-width direction view.

12. The 3DSFET device of claim 11, wherein the 1^{st} source/drain region has a greater width at a top surface portion than at a bottom surface portion, in the channel-width direction view.

13. The 3DSFET device of claim 10, wherein the 1^{st} source/drain region has a greater width at a top surface portion than at a bottom surface portion, in the channel-width direction view.

14. The 3DSFET device of claim 10, wherein the 1^{st} source/drain region has a protrusion on around a center of a top surface of the 1^{st} source/drain region, in a channel-length direction view.

15. The 3DSFET device of claim, wherein the 2^{nd} upper corner portion comprises p-type impurities or n-type impurities.

16. A method of manufacturing three-dimensional field-effect transistor (3DSFET) device, the method comprising:
forming, on a substrate, a 1^{st} source/drain region and a 2^{nd} source/drain region above the 1^{st} source/drain region; and
structuring the 1^{st} source/drain region such that the 1^{st} source/drain region has a protrusion at a 2^{nd} upper corner portion among a 1^{st} upper corner portion and the 2^{nd} upper corner portion opposite to each other in a channel-width direction view.

17. The method of claim 16, wherein a width of the 2^{nd} source/drain region is smaller than a width of the 1^{st} source/drain region, in the channel-width direction view, and
wherein the protrusion is not vertically overlapped by the 2^{nd} source/drain region.

18. The method of claim 16, the structuring the 1^{st} source/drain region comprises:
removing a 2^{nd} side edge portion among a 1^{st} side edge portion and the 2^{nd} side edge portion of the 1^{st} source/drain region to expose a portion of the substrate, below the 2^{nd} side edge portion, and a side surface of a reduced 1^{st} source/drain region, that is the 1^{st} source/drain region from which the 2^{nd} side edge portion is removed, in a channel-width direction view; and
forming an additional source/drain region based on the portion of the substrate and the side surface of the reduced 1^{st} source/drain region such that the 2^{nd} side edge portion is reformed and a protrusion is formed on the reformed 2^{nd} side edge portion, in the channel-width direction view, to obtain the structured 1^{st} source/drain region,
wherein the additional source/drain region is formed by epitaxially growing a material included in the portion of the substrate and the reduced 1^{st} source/drain region.

19. The method of claim 18, further comprising performing ion implantation on the protrusion and the reformed 2^{nd} side edge portion with p-type or n-type impurities.

20. The method of claim 16, wherein the protrusion of the structured 1^{st} source/drain region is in an extended shape in a vertical direction, a horizontal direction and a diagonal direction, in the channel-width direction view.

21-25. (canceled)
